(19) United States
(12) Patent Application Publication
(10) Pub. No.: US 2015/0093705 A1
(43) Pub. Date: Apr. 2, 2015

(54) DEMAGNETIZING APPARATUS, DRAWING APPARATUS, AND METHOD OF MANUFACTURING ARTICLE

(71) Applicant: CANON KABUSHIKI KAISHA, Tokyo (JP)

(72) Inventor: Shinji Uchida, Utsunomiya-shi (JP)

(21) Appl. No.: 14/488,357

(22) Filed: Sep. 17, 2014

(30) Foreign Application Priority Data
Oct. 1, 2013 (JP) 2013-206806

(51) Int. Cl. H01F 13/00; G03F 7/20; H01F 41/00

(52) U.S. Cl. CPC H01F 13/006; H01F 41/00; G03F 7/2037
USPC 430/296; 361/149

(57) ABSTRACT

The present invention provides a demagnetizing apparatus for demagnetization of an object, comprising a coil configured to generate a magnetic field for demagnetizing the object, and a supply device configured to supply, to the coil, an alternating current whose amplitude decreases with time, wherein the supply device supplies the alternating current to the coil such that an amplitude of the alternating current is larger than an absolute value of a current value at which magnetic saturation is occurred in the object in a first period, an absolute value of a rate of change in amplitude of the alternating current is larger than that in the first period in a second period, and an amplitude of the alternating current is smaller than an absolute value of a current value corresponding to a coercive force of the object in a third period.

### BACKGROUND OF THE INVENTION

1. Field of the Invention

The present invention relates to a demagnetizing apparatus for demagnetizing an object, a drawing apparatus, and a method of manufacturing an article.

2. Description of the Related Art

Along with micropatterning and high integration of circuit patterns in semiconductor integration circuits, attention is paid to a drawing apparatus which draws a pattern on a substrate using a charged particle beam (electron beam). Since a drawing apparatus is required to accurately position a substrate stage holding a substrate at high speed, for example, a linear motor having high positioning accuracy and a high response characteristic is used as a driving unit for driving the substrate stage. In such drawing apparatus, a magnetic shield is provided around the linear motor to prevent a magnetic field from the linear motor from acting on a charged particle beam.

However, the magnetic shield arranged as described above may become magnetized. In this case, the magnetic field from the magnetic shield may influence the charged particle beam, thereby changing the orbit of the charged particle beam. It is, therefore, necessary to attenuate the magnetism of the magnetic shield. Japanese Patent Laid-Open Nos. 2007-81981 and 2001-285886 respectively propose methods of attenuating the magnetism of a cathode ray tube device such as a television set using a cathode ray tube by winding a coil around the cathode ray tube device, and supplying an alternating current to the coil.

The methods respectively described in Japanese Patent Laid-Open Nos. 2007-81981 and 2001-285886 decrease the amplitude of the alternating current to a predetermined value with time. However, the magnitude of the predetermined value has not been mentioned.

### SUMMARY OF THE INVENTION

The present invention provides, for example, a technique advantageous in demagnetization of an object.

According to one aspect of the present invention, there is provided a demagnetizing apparatus for demagnetization of an object, the apparatus comprising: a coil configured to generate a magnetic field for demagnetizing the object; and a supply device configured to supply, to the coil, an alternating current whose amplitude decreases with time, wherein the supply device is configured to supply the alternating current to the coil such that in a first period, an amplitude of the alternating current is larger than an absolute value of a current value at which magnetic saturation is occurred in the object, in a second period after the first period, an absolute value of a rate of change in amplitude of the alternating current is larger than that in the first period, and in a third period after the second period, an amplitude of the alternating current is smaller than an absolute value of a current value corresponding to a coercive force of the object, and an absolute value of a rate of change in amplitude of the alternating current is smaller than that in the second period.

Further features of the present invention will become apparent from the following description of exemplary embodiments with reference to the attached drawings.

### BRIEF DESCRIPTION OF THE DRAWINGS

FIG. 1 is a schematic view showing a drawing apparatus according to the first embodiment;

FIG. 2 is a schematic view showing a demagnetizing apparatus according to the first embodiment;

FIG. 3 is a graph schematically showing a magnetization curve in a magnetic shield currently subjected to demagnetization;

FIG. 4 is a timing chart showing the waveform of an alternating current supplied to a coil in the demagnetizing apparatus according to the first embodiment;

FIG. 5 is a timing chart showing the waveform of the alternating current in the first period;

FIG. 6 is a timing chart showing the waveform of the alternating current in the third period;

FIG. 7 is a timing chart showing an example of the waveform of an alternating current supplied to a coil in a demagnetizing apparatus according to the second embodiment;

FIG. 8 is a timing chart showing an example of the waveform of the alternating current supplied to the coil in the demagnetizing apparatus according to the second embodiment;

FIG. 9A is a timing chart showing an example of the waveform of the alternating current supplied to the coil; and

FIG. 9B is a timing chart showing an example of the waveform of the alternating current supplied to the coil.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

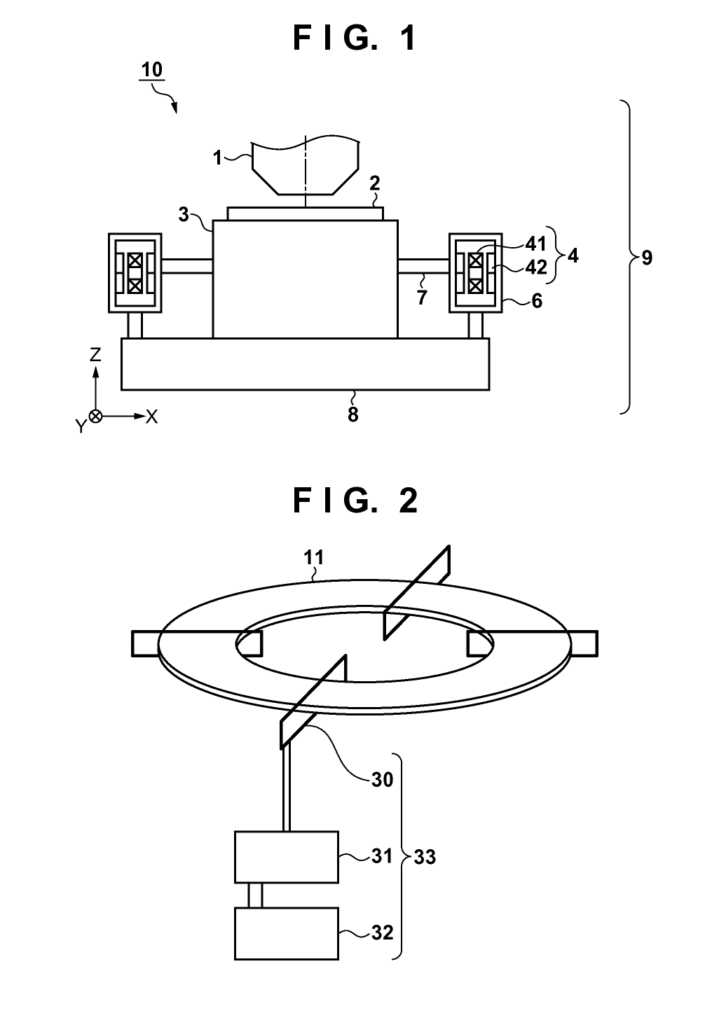

A drawing apparatus 10 according to the first embodiment will be described with reference to FIG. 1. FIG. 1 is a schematic view showing the drawing apparatus 10 according to the first embodiment. The drawing apparatus 10 includes, for example, an irradiation unit 1 for irradiating a substrate 2 with a charged particle beam, and a stage unit 9 for moving the substrate 2. The irradiation unit 1 includes, for example, a charged particle source for emitting a charged particle beam, a charged particle optical system for condensing the charged particle beam onto the substrate, and a deflector for accurately positioning the charged particle beam onto the substrate. If a magnetic field generated outside the irradiation unit 1 acts on the irradiation unit 1 with the above arrangement, it may become difficult to accurately position the charged particle beam onto the substrate. To avoid this situation, the drawing apparatus 10 is arranged within a magnetic shield room (not shown) so as to keep the magnetic field low around the apparatus.

The stage unit 9 holds the substrate 2 by, for example, vacuum chuck or electrostatic chuck, and includes a substrate stage 3 configured to be movable on a base 8, and driving units 4 for driving the substrate stage 3 via supporting members 7 in the X and Y directions. Since the drawing apparatus 10 is required to accurately position the substrate 2 at high speed, linear motors having high positioning accuracy and a high response characteristic are used as the driving units 4 for driving the substrate stage 3. Each linear motor includes, for example, a stator 41 supported by the base 8, and a movable element 42 connected to the supporting member 7. The stator 41 includes a coil, and the movable element 42 includes a permanent magnet. When the coil of the stator 41 of the linear motor is rendered conductive, a Lorentz force is generated between the coil of the stator 41 and the permanent magnet of the movable element 42. This can move the movable element 42 along the stator 41, and the driving unit 4 can drive the substrate stage 3 via the supporting member 7.

If a magnetic field is generated from the linear motor, and acts on the irradiation unit 1, it may become difficult for the driving units 4 with the above arrangement to accurately position the charged particle beam onto the substrate. To avoid this situation, a magnetic shield 6 is provided around each linear motor (each driving unit 4). The magnetic shield 6 is configured as a member including a magnetic material, and can be arranged to surround the linear motor. As a material of the magnetic shield 6, for example, a soft magnetic material such as permalloy having the property (high magnetic permeability) of quickly following a change in magnetic field is used. This can prevent the magnetic field generated from the linear motor from acting on the irradiation unit 1.

The magnetic shield room or the magnetic shield 6, however, may be magnetized in, for example, a manufacturing, assembling, or installing process. Along with the use of the drawing apparatus 10 (for example, along with the operation of the driving unit 4), the magnetic shield room or the magnetic shield 6 may be magnetized. Also, when the magnetic shield 6 for preventing the magnetic field from the linear motor from acting on the irradiation unit 1 is magnetized, the magnetic field from the magnetic shield 6 or the like may influence the charged particle beam to change its orbit. That is, it may become difficult for the irradiation unit 1 to accurately position the charged particle beam onto the substrate. It is, therefore, necessary to attenuate the magnetism of the magnetic shield 6 or the like. To do this, parts (to be referred to as shield parts 11 (objects) hereinafter) forming the magnetic shield 6 are extracted, and “demagnetization” for attenuating the magnetism of each shield part 11 is performed. A demagnetizing apparatus 33 is used for “demagnetization” of each shield part 11. The demagnetizing apparatus 33 will be described below with reference to FIG. 2. In the first embodiment, a case will be explained in which the drawing apparatus 10 and the demagnetizing apparatus 33 are configured as different apparatuses such that the demagnetizing apparatus 33 demagnetizes each shield part 11 extracted from the drawing apparatus 10. The present invention, however, is not limited to this. For example, the drawing apparatus 10 may include the demagnetizing apparatus 33 so as to demagnetize each shield part 11 while the shield part 11 is attached to the drawing apparatus 10.

FIG. 2 is a schematic view showing the demagnetizing apparatus 33 according to the first embodiment. As shown in FIG. 2, the demagnetizing apparatus 33 includes, for example, coils 30, a supply unit 31 (a supply device), and a power supply 32. Each coil 30 is wound around the extracted shield part 11, and generates a magnetic field for demagnetizing the shield part 11 (object). The supply unit 31 generates an alternating current for demagnetizing the shield part 11 using an alternating current generated by the power supply 32, and supplies the generated alternating current to the coil 30. The power supply 32 generates a current expressed by a sine function having a given amplitude I. The demagnetizing apparatus 33 shown in FIG. 2 includes a plurality of coils 30 wound around the shield part 11, and causes the supply unit 31 to supply the alternating current to the plurality of (four) coils 30 to give an alternating magnetic field to the shield part 11. The demagnetizing apparatus 33 can decrease the amplitude of the alternating magnetic field given to the shield part 11 by decreasing the amplitude of the alternating current supplied to the coils 30 with time, thereby attenuating the magnetism of the shield part 11. Although the four coils are wound around the shield part 11 in FIG. 2, the present invention is not limited to this, and at least one coil need only be wound around the shield part 11.

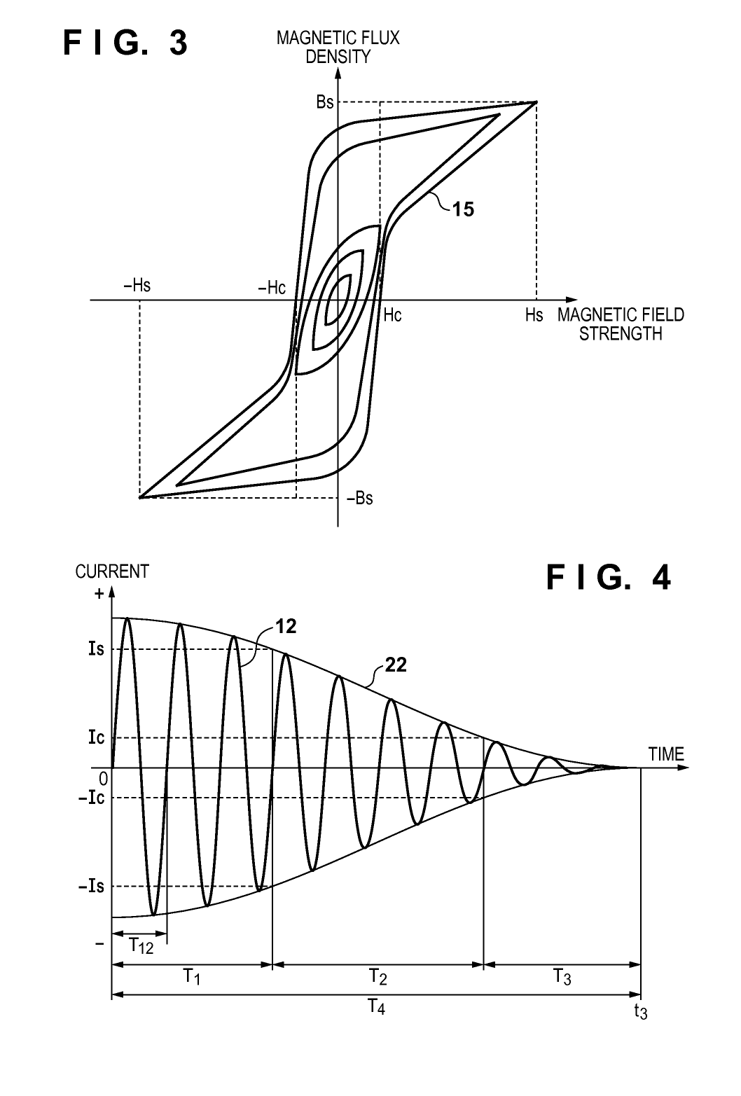

The concept of demagnetization in the magnetic shield 6 will be described with reference to FIG. 3. FIG. 3 is a graph schematically showing a magnetization curve in the shield part 11 currently subjected to demagnetization. Referring to FIG. 3, the abscissa represents a magnetic field strength, and the ordinate represents a magnetic flux density. When the alternating current is supplied to the coils 30, the magnetization curve draws a hysteresis loop 15, as shown in FIG. 3. The demagnetizing apparatus 33 can demagnetize the shield part 11 by supplying the alternating current to the coils 30 such that the hysteresis loop 15 of the magnetization curve becomes small gradually. That is, by supplying the alternating current to the coils 30 such that the amplitude of the alternating current decreases with time, it is possible to demagnetize the shield part 11. The present inventor has found that in order to sufficiently demagnetize the shield part 11, the magnitude or length of the amplitude of the alternating current in the initial stage and final stage during demagnetization of the shield part 11 is important in addition to simply decreasing the amplitude of the alternating current.

A period during which the demagnetizing apparatus 33 demagnetizes the shield part 11 is divided into, for example, a first period T₁ (initial stage), a second period T₂ (middle stage), and a third period T₃ (final stage). In this case, in the first period T₁, the demagnetizing apparatus 33 supplies the alternating current to the coils 30 such that the magnetization curve of the shield part 11 draws the large hysteresis loop 15 from a saturation magnetic flux density Bₛ and a magnetic field Hₛ to a saturation magnetic flux density −Bₛ and a magnetic field −Hₛ in the opposite direction. That is, the demagnetizing apparatus 33 supplies, to the coils 30, the alternating current having an amplitude larger than the absolute value of a current value at which magnetic saturation is occurred in the shield part 11. The saturation magnetic flux density indicates a magnetic flux density at which the shield part 11 is magnetically saturated (a magnetic flux density at which magnetic saturation is occurred in the shield part 11). In demagnetization of the shield part 11, the first period T₁ may be prolonged such that the hysteresis loop 15 is drawn at least once, that is, the alternating current for at least one cycle is supplied to the coils 30.

In the third period T₃, the demagnetizing apparatus 33 supplies the alternating current to the coils 30 such that the magnetic field strength of the magnetization curve becomes smaller than a coercive force H_{c} of the shield part 11. That is, the demagnetizing apparatus 33 supplies, to the coils 30, the alternating current having an amplitude smaller than the absolute value of a current value corresponding to the coercive force H_{c} of the shield part 11. In the third period T₃, the demagnetizing apparatus 33 supplies the alternating current to the coils 30 such that the magnetic flux density and magnetic field strength of the magnetization curve respectively become close to zero. In demagnetization of the shield part 11, the third period T₃ may be prolonged such that the hysteresis loop 15 is drawn at least twice, that is, the alternating current for at least two cycles is supplied to the coils 30.

In the second period T₂, the demagnetizing apparatus 33 decreases the amplitude of the alternating current supplied to the coils 30 such that the hysteresis loop 15 of the magnetization curve becomes small gradually, that is, the magnetic flux density and the magnetic field strength gradually decrease. In the second period T₂, the influence of a rate of decrease in amplitude of the alternating current (the absolute value of a rate of change in amplitude) on the effect of demagnetization is smaller than those in the first period T₁ and the third period T₃. In demagnetization of the shield part 11, therefore, the second period T₂ may be set short to shorten a period T₄ during which the shield part 11 is demagnetized. For example, the second period T₂ need only include the alternating current for at least one cycle. As described above, the demagnetizing apparatus 33 can attenuate the magnetism of the shield part 11 by supplying the alternating current to the coils 30 (drawing the hysteresis loop 15).

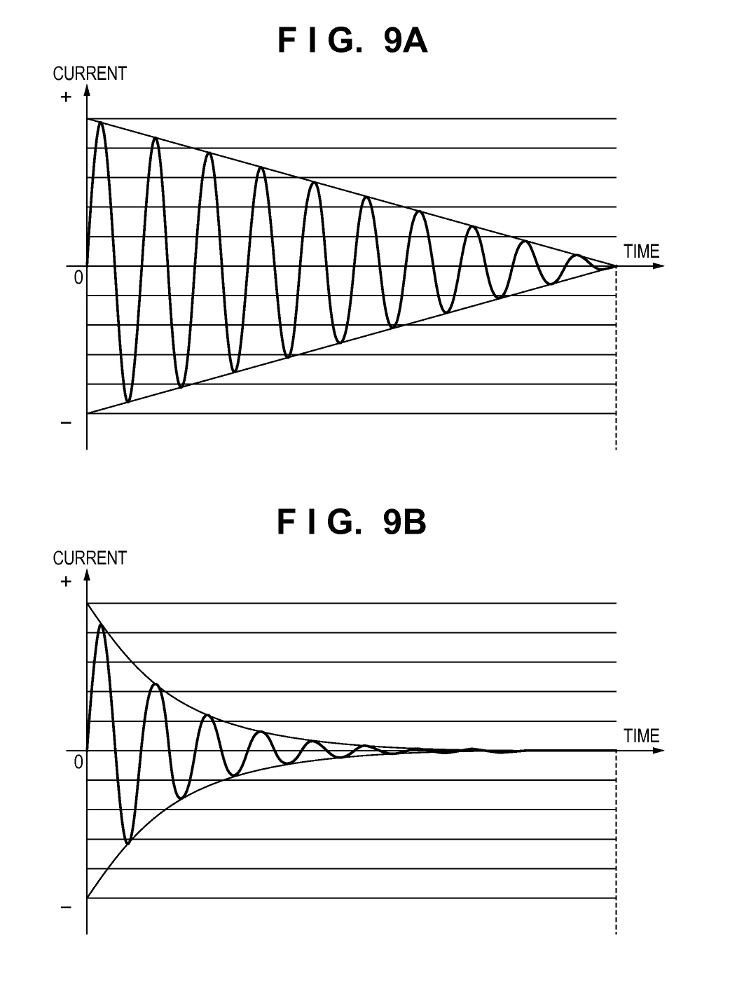

An example of the waveform of the alternating current supplied to the coils 30 will be described with reference to FIGS. 9A and 9B. FIGS. 9A and 9B are timing charts each showing an example of the waveform of the alternating current supplied to the coils 30. The waveform shown in FIG. 9A indicates that the amplitude of the alternating current linearly decreases with time while the shield part 11 is demagnetized. When the supply unit 31 supplies the alternating current with such alternating current waveform to the coils 30, it is possible to prolong the first period T₁ during which the amplitude of the alternating current is larger than the absolute value of a current value obtained when the magnetic flux density of the shield part 11 reaches the saturation magnetic flux density B. On the other hand, since the rate of change in amplitude of the current does not change even in the final stage, it may become difficult to prolong the third period T₃ during which the amplitude of the alternating current is smaller than the absolute value of a current value obtained when the magnetic field strength of the shield part 11 reaches the coercive force. That is, during the third period T₃, it may become difficult to supply, to the coils 30, the alternating current for at least two cycles, which has an amplitude smaller than the absolute value of a current value corresponding to the coercive force of the shield part 11.

The waveform shown in FIG. 9B indicates that the amplitude of the alternating current decreases according to an exponential function with time while the shield part 11 is demagnetized. When the supply unit 31 supplies the alternating current with such alternating current waveform to the coils 30, it is possible to prolong the third period T₃ during which the amplitude of the alternating current is smaller than the absolute value of the current value obtained when the magnetic field strength of the shield part 11 reaches the coercive force. On the other hand, since the rate of change in amplitude of the alternating current in the initial stage is high, it may become difficult to prolong the first period T₁ during which the amplitude of the alternating current is larger than the absolute value of the current value obtained when the magnetic flux density of the shield part 11 reaches the saturation magnetic flux density Bₛ. That is, in the first period T₁, it is impossible to supply, to the coils 30, the alternating current for at least one cycle, which has an amplitude larger than the absolute value of the current value at which magnetic saturation is occurred in the shield part 11, and it may become difficult to excite the magnetic field to a magnetic flux density at which magnetic saturation is occurred in the shield part 11.

The demagnetizing apparatus 33 (supply unit 31) of the first embodiment supplies the alternating current to the coils 30 such that the absolute value of a change in amplitude of the alternating current is expressed by a cosine wave function. When the supply unit 31 supplies the alternating current with an alternating current waveform 12 to the coils 30, in the first period T₁, it is possible to make the amplitude of the alternating current larger than the absolute value of a current value Iₛ at which magnetic saturation is occurred in the shield part 11. In the third period T₃, it is possible to make the amplitude of the alternating current smaller than the absolute value of a current value I_{c} corresponding to the coercive force H_{c} of the shield part 11. Furthermore, since it is possible to make the absolute value of the rate of change in amplitude of the alternating current in the second period T₂ larger than those in the first period T₁ and the third period T₃, the period T₄ during which the shield part 11 is demagnetized can be shortened.

The waveform 12 of the alternating current supplied to the coils 30 in the demagnetizing apparatus 33 according to the first embodiment will be described with reference to FIG. 4. FIG. 4 is a timing chart showing the waveform 12 of the alternating current supplied to the coils 30 in the demagnetizing apparatus 33 according to the first embodiment. As shown in FIG. 4, the demagnetizing apparatus 33 of the first embodiment generates the waveform 12 of the alternating current such that the amplitude of a sine wave current with a cycle T₁₂, whose polarity alternately changes in the positive and negative directions, decreases according to a curve 22 expressed by a cosine wave function with a cycle of T₄×2. The demagnetizing apparatus 33 terminates demagnetization of the shield part 11 at a time t₃ in the third period T₃ at which the tilt of the curve 22 becomes zero, that is, the amplitude of the alternating current becomes zero. The alternating current waveform 12 can be given by:

$$I ( t ) = {I}_{0} \times \frac{cos ( 2 π \cdot t / 2 {T}_{4} ) + 1}{2} \times sin ( 2 π \cdot t / {T}_{12} ) \qquad ( 1 )$$

where I₀ represents a largest value of the amplitude of the alternating current (for example, the amplitude of the alternating current generated by the power supply 32), and is set to be larger than the absolute value of the current value Iₛ at which magnetic saturation is occurred in the shield part 11. Furthermore, t represents an elapsed time in the period T₄ during which demagnetization is performed. Note that the frequency 1/T₁₂ of the alternating current may be set to be equal to or smaller than the frequency (for example, 60 Hz) of a commercial power supply such that the influence of an eddy current generated within the shield part 11 becomes small.

As indicated by equation (1), the waveform 12 of the alternating current is obtained by multiplying a sine wave “I₀×sin(2π·t/T₁₂)” having the amplitude I₀ and a change A(t) “{cos(2π·t/T₁₂)+1}/2” in amplitude representing the curve 22. The supply unit 31 supplies the alternating current with the alternating current waveform 12 to the coils 30. For example, the supply unit 31 may store the sine wave function with the cycle T₁₂ and the cosine wave function with the cycle of T₄×2, and supply the alternating current to the coils 30 based on the result of multiplying the two functions. Alternatively, the supply unit 31 may store in advance the result of multiplying two functions as a table, and supply the alternating current to the coils 30 based on the table.

The alternating current waveform 12 expressed by equation (1) above has an amplitude larger than the absolute value of the current value Iₛ at which magnetic saturation is occurred in the shield part 11 in the first period T₁, and it is possible to supply the alternating current for at least one cycle (three cycles in FIG. 4) to the coils 30. It is then possible to decrease the absolute value of the rate of change in amplitude in the first period T₁ to be smaller than that in the second period T₂. For example, FIG. 5 is a timing chart showing the waveform of the alternating current in the first period T₁. Referring to FIG. 5, |Iₙ| represents the absolute value of each amplitude which appears every half cycle. It is found that when “|Iₙ|−|Iₙ₊₁|” represents the absolute value of the rate of change in amplitude, the absolute value of the rate of change in amplitude in the first period T₁ is smaller than the rate “|I₇|−|I₈|” of change in amplitude in the second period T₂. As described above, in the first period T₁, the alternating current for at least one cycle, which has an amplitude larger than the absolute value of the current value Iₛ at which magnetic saturation is occurred in the shield part 11, is supplied to the coils 30. This can prolong the first period T₁, and draw, at least once, the hysteresis loop 15 of the magnetization curve from the magnetic field strength Hₛ at which the magnetic flux density reaches the saturation magnetic flux density Bₛ to the magnetic field strength −Hₛ at which the magnetic flux density reaches the saturation magnetic flux density −Bₛ in the opposite direction. That is, a magnetic field larger than the magnetic field of the shield part 11 before demagnetization of the shield part 11 can be reliably supplied to the shield part 11.

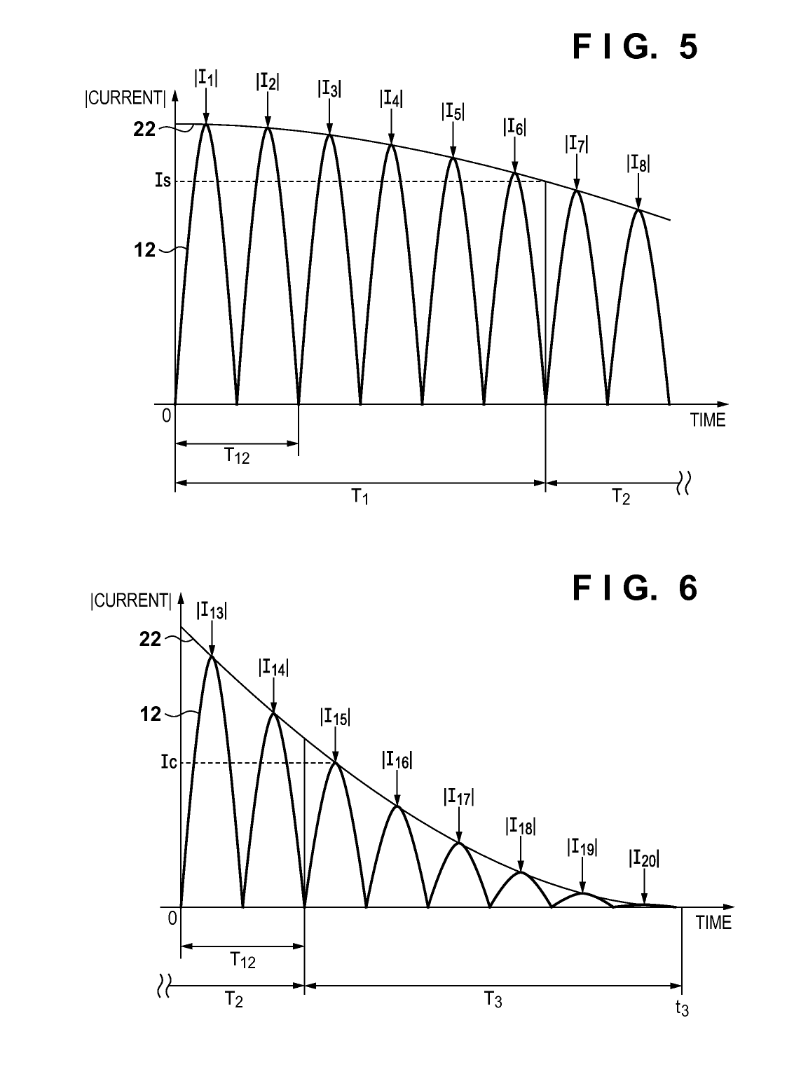

The waveform 12 of the alternating current expressed by equation (1) above has an amplitude smaller than the absolute value of the current value I_{c} corresponding to the coercive force of the shield part 11 in the third period T₃, and it is possible to supply the alternating current for at least two cycles (three cycles in FIG. 4) to the coils 30. It is then possible to decrease the absolute value of the rate of change in amplitude in the third period T₃ to be smaller than that in the second period T₂. For example, FIG. 6 is a timing chart showing the waveform 12 of the alternating current in the third period T₃. Referring to FIG. 6, |Iₙ| represents the absolute value of each amplitude which appears every half cycle. It is found that when “|Iₙ|−Iₙ₊₁|” represents the absolute value of the rate of change in amplitude, the absolute value of the rate of change in amplitude in the third period T₃ is smaller than the absolute value “|I₁₃|−|I₁₄|” of the rate of change in amplitude in the second period T₂. As described above, in the third period T₃, the alternating current for at least two cycles, which has an amplitude smaller than the absolute value of the current value I_{c} corresponding to the coercive force H_{c} of the shield part 11, is supplied to the coils 30. This can prolong the third period T₃, and draw, at least twice, the hysteresis loop 15 of the magnetization curve within the range of a magnetic field smaller than the coercive force H_{c} of the shield part 11. As a result, it is possible to reliably attenuate the magnetic field of the shield part 11 to a magnetic field smaller than the coercive force H_{c} of the shield part 11.

As described above, the demagnetizing apparatus 33 of the first embodiment causes the supply unit 31 to supply the alternating current to the coils 30 such that a change in amplitude of the alternating current is expressed by a cosine wave function. This can prolong the first period T₁ such that the supply unit 31 can supply, to the coils 30, the alternating current for at least one cycle, which has an amplitude larger than the absolute value of the current value Iₛ at which magnetic saturation is occurred in the shield part 11. It is also possible to prolong the third period T₃ such that the supply unit 31 can supply, to the coils 30, the alternating current for at least two cycles, which has an amplitude smaller than the absolute value of the current value I_{c} corresponding to the coercive force H_{c} of the shield part 11. As a result, the demagnetizing apparatus 33 of the first embodiment can accurately demagnetize the shield part 11. A case in which the shield part 11 made of a high magnetic permeability material is demagnetized has been explained in the first embodiment. However, an object to be demagnetized is not limited to the shield part 11, and any object made of a magnetic material may be demagnetized.

### Second Embodiment

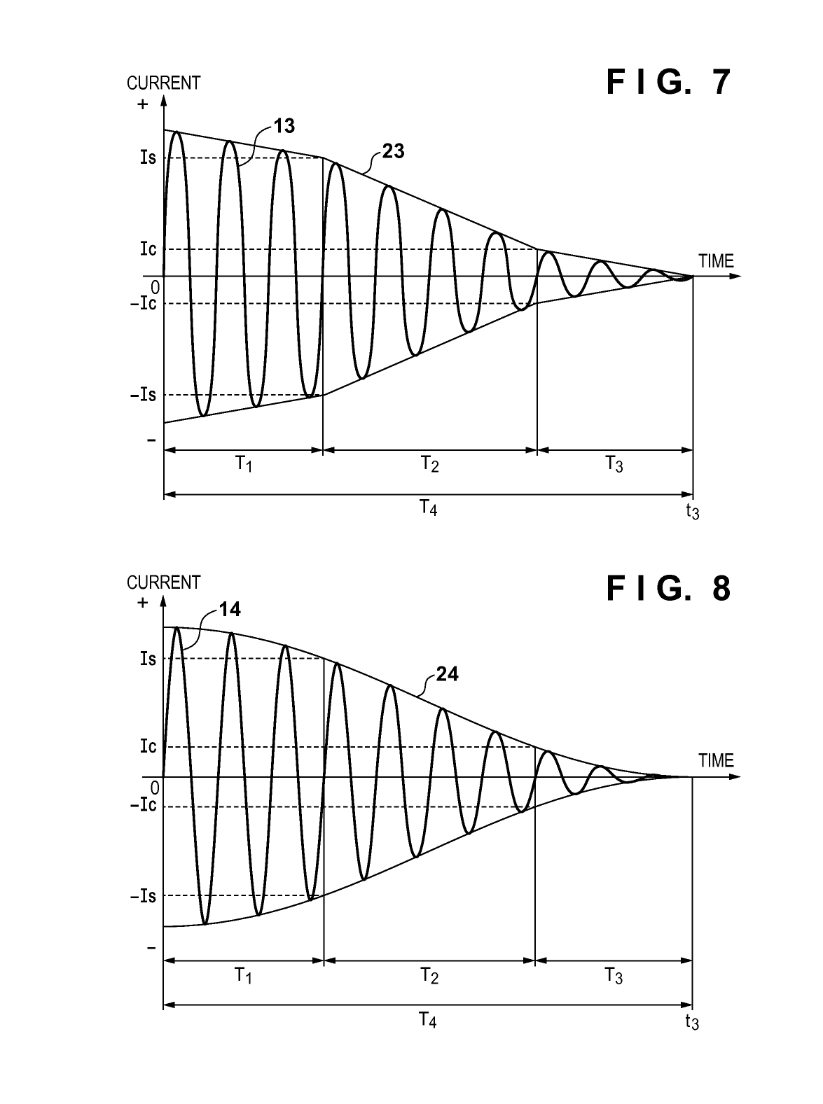

In the first embodiment, the demagnetizing apparatus 33 generates the waveform 12 of the alternating current such that a change in amplitude of the alternating current is expressed by a cosine wave function. However, the demagnetizing apparatus 33 may generate the waveform of the alternating current such that a change in amplitude of the alternating current is expressed by a function other than the cosine wave function. The waveform of the alternating current generated such that a change in amplitude of the alternating current is expressed by a function other than the cosine wave function will be described below with reference to FIGS. 7 and 8.

FIGS. 7 and 8 are timing charts each showing an example of the waveform of an alternating current supplied to coils 30. In a waveform 13 of the alternating current shown in FIG. 7, a change (line 23) in amplitude of the alternating current in each of a first period T₁, second period T₂, and third period T₃ is expressed by a function of that is linear with respect to time. In a waveform 14 of the alternating current shown in FIG. 8, a change (curve 24) in amplitude of the alternating current in a period T₄ during which a shield part 11 is demagnetized is expressed by a cubic function of time. Referring to FIG. 8, a change (curve 24) in amplitude of the alternating current is expressed by a cubic function of time. The present invention, however, is not limited to this, and the change may be expressed by a function of order not lower than 3 with respect to time.

In each of the waveforms 13 and 14 of the alternating currents shown in FIGS. 7 and 8, a change in amplitude of the alternating current in the second period T₂ is larger than that in the first period T₁, and a change in amplitude of the alternating current in the third period T₃ is larger than that in the second period T₂. The amplitude of the alternating current in the first period T₁ is larger than the absolute value of a current value Iₛ at which magnetic saturation is occurred in the shield part 11. The amplitude of the alternating current in the third period T₃ is smaller than the absolute value of a current value I_{c} corresponding to a coercive force H_{c} of the shield part 11, and becomes close to zero with time. Similarly to the first embodiment, a demagnetizing apparatus 33 (supply unit 31) can accurately demagnetize the shield part 11 by supplying the alternating current with the alternating current waveform 13 or 14 shown in FIG. 7 or 8 to the coils 30.

### Embodiment of Method of Manufacturing Article

A method of manufacturing an article according to an embodiment of the present invention is suitable for manufacturing an article, for example, a microdevice such as a semiconductor device or an element having a microstructure. The method of manufacturing an article according to this embodiment includes a step of forming a latent image pattern on a photosensitive agent applied on a substrate by using the above-described drawing apparatus including the demagnetizing apparatus (a step of performing drawing on the substrate), and a step of developing the substrate on which the latent image pattern is formed in the above step. This manufacturing method further includes other well-known steps (for example, oxidation, deposition, vapor deposition, doping, planarization, etching, resist removal, dicing, bonding, and packaging). When compared to the conventional methods, the method of manufacturing an article according to this embodiment is advantageous in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-206806 filed on Oct. 1, 2013, which is hereby incorporated by reference herein in its entirety.

1. A demagnetizing apparatus for demagnetization of an object, the apparatus comprising:
a coil configured to generate a magnetic field for demagnetizing the object; and
a supply device configured to supply, to the coil, an alternating current whose amplitude decreases with time,
wherein the supply device is configured to supply the alternating current to the coil such that in a first period, an amplitude of the alternating current is larger than an absolute value of a current value at which magnetic saturation is occurred in the object, in a second period after the first period, an absolute value of a rate of change in amplitude of the alternating current is larger than that in the first period, and in a third period after the second period, an amplitude of the alternating current is smaller than an absolute value of a current value corresponding to a coercive force of the object, and an absolute value of a rate of change in amplitude of the alternating current is smaller than that in the second period.

2. The apparatus according to claim 1, wherein the supply device is configured to supply the alternating current for at least two cycles thereof to the coil in the third period.

3. The apparatus according to claim 1, wherein the supply device is configured to supply the alternating current for at least one cycle thereof to the coil in the first period.

4. The apparatus according to claim 1, wherein the supply device is configured to supply the alternating current for at least one cycle thereof to the coil in the second period.

5. The apparatus according to claim 1, wherein
the supply device is configured to supply the alternating current to the coil such that the amplitude of the alternating current changes in accordance with a function:
$$A = \frac{cos ( 2 π \cdot t / 2 T ) + 1}{2}$$
where T represents a period in which the demagnetization is performed, and t represents an elapsed time in the period T.

6. The apparatus according to claim 1, wherein the supply device is configured to supply the alternating current to the coil such that an amplitude of the alternating current changes in accordance with a function of order not lower than 3 with respect to time.

7. The apparatus according to claim 1, wherein the supply device is configured to supply the alternating current to the coil such that an amplitude of the alternating current in each of the first period, the second period, and the third period changes in accordance with a function that is linear with respect to time.

8. The apparatus according to claim 1, wherein the supply device is configured to supply the alternating current to the coil such that an amplitude of the alternating current becomes zero in the third period.

9. The apparatus according to claim 1, further comprising a power supply configured to generate a current expressed by a sine function,
wherein the supply device is configured to generate the alternating current by changing an amplitude of current from the power supply.

10. The apparatus according to claim 1, wherein
the demagnetizing apparatus includes a plurality of the coil, and
the supply device is configured to supply the alternating current to each of the plurality of the coil.

11. A drawing apparatus for performing drawing on a substrate with a charged particle beam, the apparatus comprising:
a member including a magnetic material; and
a demagnetizing apparatus for demagnetization of the member, wherein the demagnetizing apparatus comprises:
a coil configured to generate a magnetic field for demagnetizing the object; and
a supply device configured to supply, to the coil, an alternating current whose amplitude decreases with time,
wherein the supply device is configured to supply the alternating current to the coil such that in a first period, an amplitude of the alternating current is larger than an absolute value of a current value at which magnetic saturation is occurred in the object, in a second period after the first period, an absolute value of a rate of change in amplitude of the alternating current is larger than that in the first period, and in a third period after the second period, an amplitude of the alternating current is smaller than an absolute value of a current value corresponding to a coercive force of the object, and an absolute value of a rate of change in amplitude of the alternating current is smaller than that in the second period.

12. The apparatus according to claim 11, wherein the member includes a magnetic shield.

13. A method of manufacturing an article, the method comprising:
performing drawing on a substrate using a drawing apparatus;
developing the substrate on which the drawing has been performed; and
processing the developed substrate to manufacture the article,
wherein the drawing apparatus performs drawing on the substrate with a charged particle beam, and includes:
a member including a magnetic material; and
a demagnetizing apparatus for demagnetization of the member,
wherein the demagnetizing apparatus includes:
a coil configured to generate a magnetic field for demagnetizing the object; and
a supply device configured to supply, to the coil, an alternating current whose amplitude decreases with time,
wherein the supply device is configured to supply the alternating current to the coil such that in a first period, an amplitude of the alternating current is larger than an absolute value of a current value at which magnetic saturation is occurred in the object, in a second period after the first period, an absolute value of a rate of change in amplitude of the alternating current is larger than that in the first period, and in a third period after the second period, an amplitude of the alternating current is smaller than an absolute value of a current value corresponding to a coercive force of the object, and an absolute value of a rate of change in amplitude of the alternating current is smaller than that in the second period.
